(19) United States
(12) Patent Application Publication
(10) Pub. No.: US 2014/0264346 A1
(43) Pub. Date: Sep. 18, 2014

(54) INTEGRATED PHOTODIODE

(71) Applicant: Seagate Technology LLC, Cupertino, CA (US)

(72) Inventors: Ned Tabat, Chanhassen, MN (US); Xiaoyue Huang, Eden Prairie, MN (US)

(73) Assignee: Seagate Technology LLC, Cupertino, CA (US)

(21) Appl. No.: 14/209,511

(22) Filed: Mar. 13, 2014

Related U.S. Application Data
(60) Provisional application No. 61/800,409, filed on Mar. 15, 2013.

(51) Int. Cl. H01L 31/0376; H01L 31/18

(52) U.S. Cl. CPC H01L 31/03762; H01L 31/1804
USPC 257/53; 438/69

(57) ABSTRACT

In accordance with one implementation, a photodiode may be integrated by thin film processing within a slider. In accordance with another implementation, an apparatus can be configured to include a slider, a first layer of a metal disposed within the slider, a layer of amorphous silicon disposed adjacent the first layer of metal, a second layer of metal disposed adjacent the layer of amorphous silicon, and wherein the first layer of metal, the layer of amorphous silicon, and the second layer of metal are operable as a photodiode.

### CROSS-REFERENCE TO RELATED APPLICATIONS

The present application claims benefit of priority to U.S. Provisional Patent Application No. 61/800,409 entitled “Method and Apparatus for Integrated Photodiode” and filed on 15 Mar. 2013, which is specifically incorporated by reference herein for all that it discloses or teaches.

### BACKGROUND

Data storage devices can utilize light in a variety of ways. One example is a hard disc drive (HDD) that utilizes heat assisted magnetic recording (HAMR) to record data. In such an implementation, a light source such as a laser can be mounted onto a transducer, such as a slider, so as to heat a portion of a disc during a write operation. The light emitted from the laser can be concentrated so as to heat a targeted portion of the disc prior to performing a write operation. Some devices utilize a waveguide and a near-field transducer to further manipulate the emitted light. This is but one example of a device that utilizes light.

### SUMMARY

In accordance with one implementation, a photodiode is integrated by thin film processing within a transducer.

In accordance with another implementation, an apparatus is configured to include a slider, a first layer of a metal disposed within the slider, a layer of amorphous silicon disposed adjacent the first layer of metal, a second layer of metal disposed adjacent the layer of amorphous silicon, and wherein the first layer of metal, the layer of amorphous silicon, and the second layer of metal are operable as a photodiode.

In yet another implementation, a method is implemented by utilizing thin film deposition to configure a photodiode within a slider.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Other features, details, utilities, and advantages of the claimed subject matter will be apparent from the following more particular written Detailed Description of various implementations and implementations as further illustrated in the accompanying drawings and defined in the appended claims.

### BRIEF DESCRIPTION OF THE DRAWINGS

A further understanding of the nature and advantages of the present technology may be realized by reference to the figures, which are described in the remaining portion of the specification.

FIG. 1 illustrates an example block diagram of a hard disc drive system that utilizes a photodiode integrated within a slider, in accordance with one implementation.

FIG. 2 illustrates a photodiode integrated within a slider, in accordance with one implementation.

FIG. 3 illustrates a photodiode configured from amorphous semiconductor, in accordance with one implementation.

FIG. 4 shows a flow chart illustrating a method of producing a photodiode, in accordance with one implementation.

FIG. 5 shows another flow chart illustrating a method of producing a photodiode, in accordance with another implementation.

FIG. 6 shows a placement of a photodiode in accordance with one implementation proximate to a substantially planar core.

FIG. 7 illustrates shows another flow chart illustrating feedback operations using the transducer disclosed herein.

### DETAILED DESCRIPTION

Implementations of the present technology are disclosed herein in the context of a disc drive system. However, it should be understood that the technology is not limited to a disc drive system and could readily be applied to other devices, as well.

Heat assisted magnetic recording (HAMR) generally refers to the concept of locally heating a recording medium to reduce the coercivity of the medium. Such reduced coercivity allows the applied magnetic writing fields to more easily direct the magnetization within the recording medium during the temporary magnetic softening caused by the heat source. HAMR allows for the use of small grain media, with a larger magnetic anisotropy at room temperature to assure sufficient thermal stability, which is desirable for recording at increased areal densities. HAMR can be applied to any type of magnetic storage media including tilted media, longitudinal media, perpendicular media, and patterned media. By heating the media, the Hc or coercivity is reduced such that the magnetic write field is sufficient to write to the media. Once the media cools to ambient temperature, the coercivity has a sufficiently high

An implementation of the heat-assisted magnetic recording (HAMR) disclosed herein includes a plasmonic transducer as a localized heat source that enables both high track- and high linear-density recording on specialized magnetic discs. In accordance with one implementation, a photodiode is integrated within a device utilizing thin film processing techniques. This integration within the device allows the photodiode to serve as a sensor within the device. This implementation is particularly useful for integrating a photodiode within a slider. Furthermore, the implementation of the photodiodes disclosed herein are integrated within a slider body such that they can be fabricated using thin film head wafer processes. Such implementations of photodiodes have significant frequency bandwidth and signal to noise ratio advantages over thermal sensors.

Sliders can be used, for example, as part of a hard disc drive in order to perform read/write operations. Some applications of sliders involve the use of laser-emitted light; so, a photodiode integrated within the slider may serve as a sensor to sense the laser-emitted light being routed through the slider. The laser-emitted light can be transmitted through the slider by a waveguide, for example. The laser-emitted light may also be concentrated and localized by a near field transducer that is integrated within the slider. The energy density produced by the near field transducer is directly related to the intensity of laser light used to excite it. The quality of the recording produced by HAMR depends strongly on localized energy density imparted by the near field transducer on the recording medium. Since the laser light intensity can vary, it needs to be regulated by a sensor+feedback circuit. Photodiodes provide an excellent means for fast and accurate intensity measurement. A small portion of the laser light is diverted to the photodiode and monitored for changes in the overall intensity. There are several different positions within the light path where one might choose to sense the intensity of the light with the photodiode.

An implementation of a slider disclosed herein provides making a photodiode using an amorphous semiconductor as the active sensing element, such as amorphous silicon. The amorphous silicon can be deposited by thin film processing techniques as part of a thin film wafer manufacturing process. The active layer converts light energy to electric current. Furthermore, electrodes needed to sense the photocurrent can be deposited in the wafer process, as metal thin films. The resulting slider can then include an integrated photodiode that generates a current when photons are directed onto the amorphous silicon. The performance of the photodiode can be controlled by doping the amorphous silicon with hydrogen. This doping can allow the photodiode to generate a strong output current in response to sensing photons that are at wavelengths between about 700-900 nm range, which is a useful range for HAMR technology. Specifically, the photodiode provides absorption coefficients in the range of 800-1000 cm⁻¹ in the wavelength range of interest for HAMR.

Referring now to FIG. 1, an example block diagram 100 of a hard disc drive that utilizes a photodiode integrated within a slider can be seen, in accordance with one implementation. It should be understood, however, that the described technology may be employed with a variety of systems and types of storage media, including continuous magnetic media, heat-assisted magnetic recording media, etc. A disc 102 rotates about a spindle center or a disc axis of rotation 104 during operation. The disc 102 includes an inner diameter 106 and an outer diameter 108 between which are a number of concentric data tracks 110.

Information may be written to and read from the disc 102 in different data tracks 110. A transducer head 124 is mounted on an actuator arm 126 of an actuator assembly 120 at an end distal to an actuator axis of rotation 122 and the transducer head 124 flies in close proximity above the surface of the disc 102 during a disc operation. The actuator assembly 120 rotates during a seek operation about the actuator axis of rotation 122 positioned adjacent to the disc 102. The seek operation positions the transducer head 124 over a target data track of the data tracks 110.

The exploded view 140 illustrates a side view of the transducer head 124 (not to scale). The transducer head 124 may be located on a slider (not shown) that is attached to the actuator arm 126. In one implementation, a laser energy source 146 is used to provide laser energy to via a waveguide 144 to a spot on the media 150. In an alternative implementation, a near field transducer (NFT) (not shown) may be provided close to the media 150 that concentrates the laser energy to heat a spot on the media 150. The amount of laser energy provided to a particular spot on the media 150 or to the NFT may be monitored and controlled using a feedback mechanism that uses a photodiode 142 located near the media 150 to receive the laser energy, convert a sampled portion of the laser energy into current or voltage that can be measured and fed back to the laser energy source 146.

In the illustrated implementation, the photodiode 142 is represented as being integrated within the transducer head 124. Furthermore, a waveguide 144 is shown adjacent to the photodiode 142 and also integrated within the transducer head 124. In one implementation, the photodiode 142 is located close to a writer (not shown) on the transducer head 124 such that when energy, such as light energy, is transmitted to the photodiode 142, it generates output signal in response to laser signal from the waveguide 144 in form of current or voltage. The output signal from the photodiode 142 may be used for monitoring the laser power delivered by the laser energy source 146 and to provide feedback to the laser energy source 146.

In one implementation, the photodiode 142 may be made of semiconductor material. Specifically, the photodiode 142 may be made of amorphous semiconductor material such as amorphous silicon or aSi. Furthermore, the electrical contacts to the photodiode 142 may be metal electrodes that are directly attached to an aSi absorption layer of the photodiode 142. The metal and aSi absorption layer interfaces of the photodiode 142 may form a schottky barrier that is rectifying. As a result, the sandwiched metal-semiconductor-metal stack of the photodiode 142 constitutes a pair of back-to-back schottky diodes.

In an alternative implementation, the photodiode 142 may be made of hydrogenated aSi. Such an hydrogenated aSi may be fabricated by thin film deposition method including sputtering an Si target with hydrogen, by evaporation (single source or co-evaporation, possibly with supplementary H2), thermal chemical vapor deposition plasma enhanced chemical vapor deposition (PECVD), atomic layer deposition, ion beam deposition (possibly with supplementary H2), pulsed laser deposition, etc.

FIG. 2 illustrates waveguide sampling configurations 200 and 250 including an integrated photodiode. Specifically, FIG. 2 illustrates a photodiode within a waveguide portion of a transducer. The configuration 200 is a slab waveguide configuration including a light source 202, a focusing mirror 204, and a photodiode 206. The light source 202 may be a laser light source that generates a light beam with an intensity profile 210 that is incident on the focusing mirror 204. The focusing mirror 204 focuses the light beam to an NFT (not shown). A portion 212 of the light beam incident on the focusing mirror is sampled by the photodiode 206, which generates a feedback signal between a first and a second diodes (not shown) attached to the photodiode 206. The feedback signal is sent to the light source 202. The photodiode 206 may be made of amorphous silicon. Thus, the photodiode 206 is formed such that it does not interrupt the light that will be incident on the NFT.

The waveguide sampling configuration 250 is a channel waveguide configuration that includes a first channel waveguide 252 that receives light from a light source (not shown) and redirects that light to an NFT (not shown). A small portion of the light signal travelling through the first channel waveguide 252 is diverted to a coupling channel waveguide 254. The diverted light traveling through the coupling channel waveguide 254 is incident upon a photodiode that is integrated within a slider that includes the waveguide sampling configuration 250. The photodiode 256 may be made of amorphous silicon. The photodiode 256 measures the energy of the incident light and generates a feedback signal between a first and a second diodes (not shown) attached to the photodiode 256. The feedback signal is sent to the light source. Thus, the photodiode 256 is formed such that it does not interrupt the light that will be incident on the NFT.

FIG. 3 illustrates a photodiode 300 configured from an amorphous semiconductor, such as amorphous silicon, in accordance with one implementation. A substrate layer 302, such as AlTiC is shown as the bottom layer in the figure. A layer 304 such as alumina (Al₂O₃) can be deposited on the substrate layer 302 so as to prepare a relatively smooth surface. A hole can be formed through the substrate and alumina layers so as to permit a wire 314 to be configured in the hole.

The photodiode 300 includes a first metal layer 306 deposited to form a first electrode layer for the photodiode 300. A photo detector layer 308 of an amorphous semiconductor, such as amorphous silicon, can be deposited on the first metal layer 306. In one implementation, the amorphous silicon of the photo detector layer 308 can be hydrogenated. One manner of depositing the amorphous silicon of the photo detector layer 308 is to sputter the amorphous silicon onto the metal layer 306. Once the amorphous silicon is deposited, a second layer of metal 310 can be deposited as the second electrode. Subsequent layers (not shown) may also be configured on the second layer of metal 310. Wires 312 and 314 can be coupled with metal layers 306 and 310 respectively. The wires can extend outside the device that the photodiode 300 is being fabricated within. For example, the wires 312 and 314 can be routed out of a slider to a feedback controller device for a laser generating the light that is measured by the photodiode 300.

As noted in FIG. 3, amorphous silicon and metal are interfaced as part of the manufacturing process. Metal-aSi interfaces between the metal layers 306 and 310 and the photo detector layer 308 form Schottky barriers and are rectifying. The sandwiched metal-semiconductor-metal (MSM) stack described in FIG. 3 constitutes a pair of back-to-back Schottky diodes. Any external bias voltage will appear primarily across the reversed biased junction and, for undoped aSi thin films, will likely penetrate through to the other junction electrode. Hence, a relatively large and uniform electric field that aids carrier transport can be maintained throughout the absorption layer. In addition to the aSi:H MSM described in FIG. 3, other semiconductors can be used in amorphous form. Most amorphous semiconductors, including aSi, can be doped into a p-i-n junction stack for reverse-biased high internal field operation, if desired.

The choice of metals used for electrodes 306 and 310 depends on many factors, but a number of good candidates exist. For example, a platinum (Pt)-aSi Schottky junction offers a barrier value of 0.7 V. Alternatively, tantalum (Ta), a commonly used element in the transducer process can also be used with comparable performance. In one implementation, only one of the two junctions—most likely the aSi-on-metal interface—is rectifying. The series resistance of the photodiode 300 can be reduced if the second interface electrode—metal-on-aSi—is one that forms a smaller barrier. Metals that accomplish this are Au or Ni, for example.

FIG. 4 shows a flow chart 400 illustrating a method of producing a photodiode, in accordance with one implementation. Namely, FIG. 4 shows that thin film deposition can be utilized to configure a photodiode within a slider. An operation 402 forms a thin film deposition method to form a photo detector layer made of semiconductor material. For example, the operation 402 may form the photo detector layer of amorphous silicon or hydrogenated amorphous silicon. An operation 404 forms wire connectors that connect electrodes of the photodiode to a laser energy source so that the photodiode can be used to provide feedback to the laser energy source.

FIG. 5 shows another an alternative flow chart 500 illustrating a method of producing a photodiode, in accordance with certain implementations. In operation block 502, a first metal electrode is deposited. The metal electrode layer can be deposited on a layer of alumina that has been deposited on a substrate layer, such as AlTiC for example. AlTiC is a particularly useful substrate for fabricating recording heads and is also an amorphous material.

Operation block 504 shows that amorphous silicon (aSi) can be doped with hydrogen. Doping the amorphous silicon with hydrogen allows the performance of the doped amorphous silicon to be controlled. By doping the amorphous silicon so that the photodiode operates in a linear regime, the photocurrent produced by the photodiode will be linearly proportional to an incident light power over a wide range of values. The doping can be accomplished in a variety of ways. Hydrogenated amorphous silicon (aSi:H) can be generated by various methods of thin film deposition including, for example, sputtering (using a Si target with H₂), evaporation (single source or co-evaporation, possibly with supplementary H₂), chemical vapor deposition (thermal or plasma enhanced), atomic layer deposition, ion beam deposition (possibly with supplementary H₂), or pulsed laser deposition.

In accordance with certain implementations, one type of aSi:H film can be used that has exceptionally large sub-bandgap optical absorption while maintaining good mechanical film properties. This type of aSi:H can be produced by plasma enhanced chemical vapor deposition (PECVD). The temperature of a heater, such as a susceptor, is controlled at about 150° C. to about 200° C. (e.g., 150° C. or 180° C.). Argon and silane gases can be injected into the process chamber from a showerhead at the top. An argon-to-silane ratio of about 5.4 with silane at about 300 sccm to about 400 sccm (e.g., 350 sccm) can be used. The pressure can be maintained between about 2.0 Torr and about 4.0 Torr (e.g., 3.2 Torr). High frequency RF power of about 150 W to about 350 W (e.g., 200 W) can be applied to generate plasma. A deposition rate of about 1-5 nm/sec (prefer 3.2 nm/sec) can be achieved. A target film thickness is about 500 to about 800 nm. The roughness of 500 nm film, for example, is about 1.5 nm rms. Refractive index of this film in the near infrared wavelength range is about 3.8.

Thus, operation block 504 also illustrates that an amorphous semiconductor such as aSi:H can be deposited onto the first metal electrode. Operation block 506 shows that a second metal electrode can be deposited.

FIG. 6 illustrates another example of a photodiode 600 fabricated adjacent to a planar core 602 that transmits laser-emitted light. FIG. 6 shows that the width of the amorphous semiconductor 604 can be limited to less than 1 micrometer. For example, in one implementation the thickness of amorphous silicon 604 is limited to less than one micrometer for transit time considerations. The example shown in FIG. 6 is a cross-sectional view of the planar core 602 that is surrounded by claddings 606, 608. The thickness of the photodiode 600 is fabricated to be as wide as the dimension shown for the planar core 602 in FIG. 6 so that the incident light on the amorphous semiconductor 604 can be used most efficiently. The amorphous semiconductor 604 is located between a top metal layer 610 and a bottom metal layer 612. The top metal layer 610 and the bottom metal layer 612 may be used to connect the output of the photodiode 600 to a laser energy source (not shown).

FIG. 7 illustrates another flow chart 700 illustrating feedback operations using the photodiodes disclosed herein. An operation 702 receives light beam from a light source, such as a laser source, etc. The operation may receive the light beam in a waveguide in a slab waveguide configuration, in a channel waveguide configuration, etc. An operation 704 diverts a portion of the light beam to a photodiode. For example, a portion of the light beam incident on a focusing mirror is diverted to the photodiode. Alternatively, a portion of the light beam traveling through a waveguide may be diverted to another waveguide, which carries the diverted portion to a photodiode.

An operation 706 measures the diverted beam incident upon the photodiode to generate a signal. For example, the photodiode may be configured to be connected to two electrodes and to generate a voltage signal between the two electrodes. An operation 708 feeds back the signal generated at the photodiode to the light source. The light source may use the feedback signal from the photodiode to adjust the intensity of light generated by the light source.

Because photodiodes have significant frequency bandwidth and signal to noise advantages over thermal sensors, photodiodes can be of beneficial use. It is noted that many of the structures, materials, and acts recited herein can be recited as means for performing a function or step for performing a function. Therefore, it should be understood that such language is entitled to cover all such structures, materials, or acts disclosed within this specification and their equivalents, including any matter incorporated by reference.

The above specification, examples, and data provide a complete description of the structure and use of example implementations. Because many alternate implementations can be made without departing from the spirit and scope of the invention, the invention resides in the claims hereinafter appended. Furthermore, structural features of the different implementations may be combined in yet another implementation without departing from the recited claims.

What is claimed is:

1. An apparatus comprising:
a photodiode integrated by within a slider, wherein the photodiode comprises a photo detector layer of amorphous silicon.

2. The apparatus of claim 1 wherein the photo detector layer comprises hydrogenated amorphous silicon.

3. The apparatus of claim 1 wherein the photo detector layer comprises amorphous silicon doped with hydrogen.

4. The apparatus of claim 1 wherein the photo detector layer of amorphous silicon is disposed above an amorphous AlTiC substrate.

5. The apparatus of claim 1 wherein the photodiode comprises a metal in contact with the photo detector layer of amorphous silicon to form an electrode for the photodiode.

6. The apparatus of claim 5 wherein the metal in contact with the amorphous semiconductor forms a Schottky barrier.

8. The apparatus of claim 1 wherein the photodiode is disposed adjacent a waveguide integrated within the slider.

9. The apparatus of claim 1 wherein the photodiode is formed adjacent a focusing mirror in a slab waveguide configuration.

10. The apparatus of claim 1 wherein the photodiode is formed adjacent a coupling channel in a channel waveguide configuration.

11. An apparatus comprising:
a slider;
a first layer of a metal disposed within the slider;
a layer of amorphous silicon disposed adjacent the first layer of metal;
a second layer of metal disposed adjacent the layer of amorphous silicon; and
wherein the first layer of metal, the layer of amorphous silicon, and the second layer of metal are operable as a photodiode.

12. The apparatus of claim 11 wherein the layer of amorphous silicon is disposed proximate to a waveguide.

13. A method comprising:
fabricating a photodiode within a slider using thin film deposition.

14. The method of claim 13 wherein fabricating the photodiode further comprising fabricating the photodiode having a photo detector layer of amorphous silicon.

15. The method of claim 14 wherein fabricating the photodiode further comprising depositing the amorphous silicon using sputtering.

16. The method of claim 14 wherein fabricating the photodiode further comprising doping the amorphous silicon with hydrogen.

17. The method of claim 14 wherein an amorphous semiconductor of the photodiode is disposed above an amorphous AlTiC substrate.

18. The method of claim 14 wherein configuring the photodiode comprises:
depositing a metal in contact with the amorphous silicon to form an electrode for the photodiode.

19. The method of claim 13 wherein fabricating a photodiode further comprising fabricating the photodiode adjacent a coupling channel in a channel waveguide configuration.

20. The method of claim 13 wherein fabricating a photodiode further comprising fabricating the photodiode adjacent a focusing mirror in a slab waveguide configuration.
